(19) United States
(12) Patent Application Publication
(10) Pub. No.: US 2003/0178669 A1
(43) Pub. Date: Sep. 25, 2003

(54) Nonvolatile semiconductor memory and programming methods thereof

(76) Inventor: Yuichi Kunori, Tokyo (JP)

Correspondence Address: MCDERMOTT, WILL & EMERY, 600 13th Street, N.W., Washington, DC, 20005-3096, US

(21) Appl. No.: 10/388,633

(22) Filed: Mar. 17, 2003

(30) Foreign Application Priority Data
Mar. 19, 2002 (JP) 2002-076138

(51) Int. Cl. H01L 21/8238; H01L 29/76

(52) U.S. Cl. 257/314; 257/315; 257/317; 438/201; 438/211

(57) ABSTRACT

A nonvolatile semiconductor memory for storing electrical charge to store information is provided. The memory includes a semiconductor substrate having a pair of bit lines disposed substantially in parallel with each other, and a channel region sandwiched between the bit lines; an embedded gate extending above the channel region substantially in parallel with the bit lines, the embedded gate made of a conductive layer being provided via ONO film made of a nitride film sandwiched by oxide films; a floating gate made of a conductive layer provided above the channel region via gate oxide film, along the embedded gate; an insulating layer covering the floating gate and the embedded gate; and a word line provided on the insulating layer on the floating gate, substantially orthogonal to the bit lines. Electrical charge is stored into the floating gate and/or the nitride film included in the ONO film.

### CROSS-REFERENCE TO RELATED APPLICATIONS

Related patent application is commonly assigned Japanese Patent Applications No. 2002-76138 filed on Mar. 19, 2002, which is incorporated by reference into the present patent application.

### BACKGROUND OF THE INVENTION

1. Field of the Invention

The present invention relates to a nonvolatile semiconductor memory and particularly to a fast reprogrammable nonvolatile semiconductor memory having a small memory cell area.

2. Description of the Related Art

FIG. 23 is a sectional view of a nonvolatile semiconductor memory described in JP, 2001-85541, A, indicated in its entirety as 500. The nonvolatile semiconductor memory 500 includes silicon substrate 501. Provided on the silicon substrate 501 is a gate oxide film 502 made of silicon oxide. Deposited on the gate oxide film 502 is a polycrystalline silicon layer. Grooves are formed in the polycrystalline silicon layer. The polycrystalline silicon layer sandwiched between the grooves forms a floating gate (FG) 503. A silicon oxinitride film 504 is formed on the wall surface of each groove. Loading into the grooves are embedded gates (third gates) 505 and 506 and a silicon oxide film 507. Formed on the floating gate 503 and the oxide silicon film 507 as an insulating layer are a silicon oxide film 508, a silicon nitride film 509, and a silicon oxide film 510. A word line 511 made of polycrystalline silicon is formed thereon. On the other hand, diffusion layers are selectively provided in the silicon substrate 501 to form a local bit line 512 and a local source line 513.

FIG. 24 shows an example of a step of writing into the nonvolatile semiconductor memory 500. As shown in FIG. 24, the embedded gates 505 and 506 are set to 0V and 2V, respectively. The word line 511 is set to 12V. The local bit line 512 is set to 5V and a local source line is set to 0V. In this state, electrons move from the local source line 513 to the local bit line 512 (see arrow 520). These electrons are attracted by the voltage applied to the word line 511 (see arrow 521), and injected into the floating gate 503 (injection of channel hot electrons (CHE)). Especially, application of a low voltage to the embedded gate 506 increases the efficiency of generation of hot electrons. Thereby, programming (injection of electrons into the floating gate 503) can be performed for a short period of time even with a small current.

The nonvolatile semiconductor memory 500 is structured to store one bit into one cell (1 bit/cell). This poses a problem: even when the cell area is 4F² (F being the minimum working dimension), i.e. the minimum cell area, the cell area per bit is not below 4F².

### SUMMARY OF THE INVENTION

The present invention aims to provide a nonvolatile semiconductor memory having a cell area per bit less than 4F².

The present invention provides a nonvolatile semiconductor memory for storing electrical charge to store information. The memory includes a semiconductor substrate having a pair of bit lines disposed substantially in parallel with each other, and a channel region sandwiched between the bit lines; an embedded gate extending above the channel region substantially in parallel with the bit lines, the embedded gate made of a conductive layer being provided via ONO film made of a nitride film sandwiched by oxide films; a floating gate made of a conductive layer provided above the channel region via gate oxide film, along the embedded gate; an insulating layer covering the floating gate and the embedded gate; and a word line provided on the insulating layer on the floating gate, substantially orthogonal to the bit lines. Electrical charge (electron) is stored into the floating gate (stacked gate type memory section) and/or the nitride film included in the ONO film (MONOS type memory section).

For this nonvolatile semiconductor memory, high-efficient writing into the stacked gate type memory section and the MONOS type memory section can be performed with high efficiency of generation of hot electrons. Additionally, the use of this structure can reduce the cell area per bit, in comparison with that of a conventional nonvolatile semiconductor memory.

The present invention also provides a method of programming the above-mentioned nonvolatile semiconductor memory. The method includes the steps of: storing electrical charge moving from the second bit line to the first bit line into the floating gate and/or storing electrical charge moving from the first bit line to the second bit line into the ONO film.

For this method, high-efficient writing into the stacked gate type memory section and the MONOS type memory section can be performed with high efficiency of generation of hot electrons.

The present invention further provides a method of producing the nonvolatile semiconductor memory. The method includes: a step of preparing a semiconductor substrate having a defined channel region; a deposition step of laminating a gate oxide film and a first conductive layer on the channel region; an etching step of etching the first conductive layer until at least the gate oxide film is exposed, to form a groove; a step of forming a pair of bit lines sandwiching the channel region so that the bit lines are substantially in parallel with the groove; an ONO film forming step of forming ONO film made of an oxide film, a nitride film, and an oxide film on the inner wall of the groove; an embedding step of loading a second conductive layer into the groove covered with the ONO film, to form the second conductive layer as an embedded gate; an insulating step of forming an insulating layer covering the first conductive layer and the embedded gate; a step of depositing a third conductive layer on the insulating layer, and etching the third conductive layer to form a word line; and a step of etching the first conductive layer to leave the first conductive layer only below the word line as a floating gate.

### BRIEF DESCRIPTION OF THE DRAWINGS

FIG. 1 is a sectional view of a nonvolatile semiconductor memory according to a preferred embodiment 1 of the present invention;

FIG. 2 is a top view of the nonvolatile semiconductor memory according to a preferred embodiment 1 of the present invention;

FIGS. 3-8 are schematic views showing steps of writing into the nonvolatile semiconductor memory according to a preferred embodiment 1 of the present invention;

FIGS. 9 and 10 are schematic views showing steps of reading from the nonvolatile semiconductor memory according to a preferred embodiment 1 of the present invention;

FIG. 11 is a schematic view showing a step of erasing information in the nonvolatile semiconductor memory according to a preferred embodiment 1 of the present invention;

FIG. 12 is a flowchart showing a process of writing into the nonvolatile semiconductor memory according to a preferred embodiment 1 of the present invention;

FIGS. 13-16 are schematic views showing steps of writing into the nonvolatile semiconductor memory according to a preferred embodiment 1 of the present invention;

FIG. 17 is a sectional view of another nonvolatile semiconductor memory according to a preferred embodiment 1 of the present invention;

FIG. 18 is a sectional view of still another nonvolatile semiconductor memory according to a preferred embodiment 1 of the present invention;

FIGS. 19A-19G are sectional views showing steps of producing a nonvolatile semiconductor memory according to a preferred embodiment 2 of the present invention;

FIG. 20 is a sectional view of a nonvolatile semiconductor memory according to a preferred embodiment 3 of the present invention;

FIGS. 21A-21F are sectional views showing steps of producing the nonvolatile semiconductor memory according to a preferred embodiment 3 of the present invention;

FIG. 22 is a sectional view of another nonvolatile semiconductor memory according to a preferred embodiment 3 of the present invention;

FIG. 23 is a sectional view of a conventional nonvolatile semiconductor memory; and

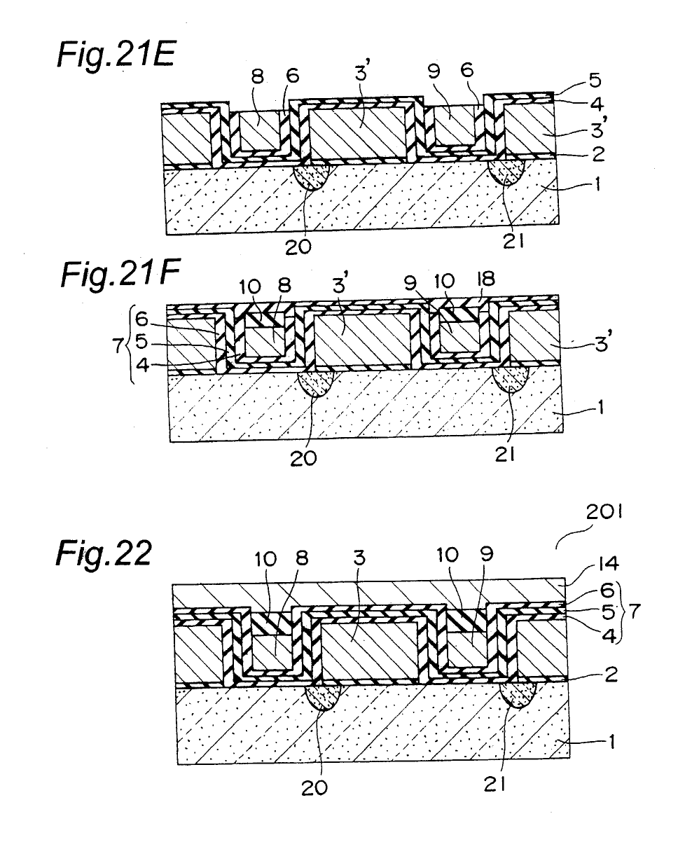

FIG. 24 is a schematic view showing a step of writing into the conventional nonvolatile semiconductor memory.

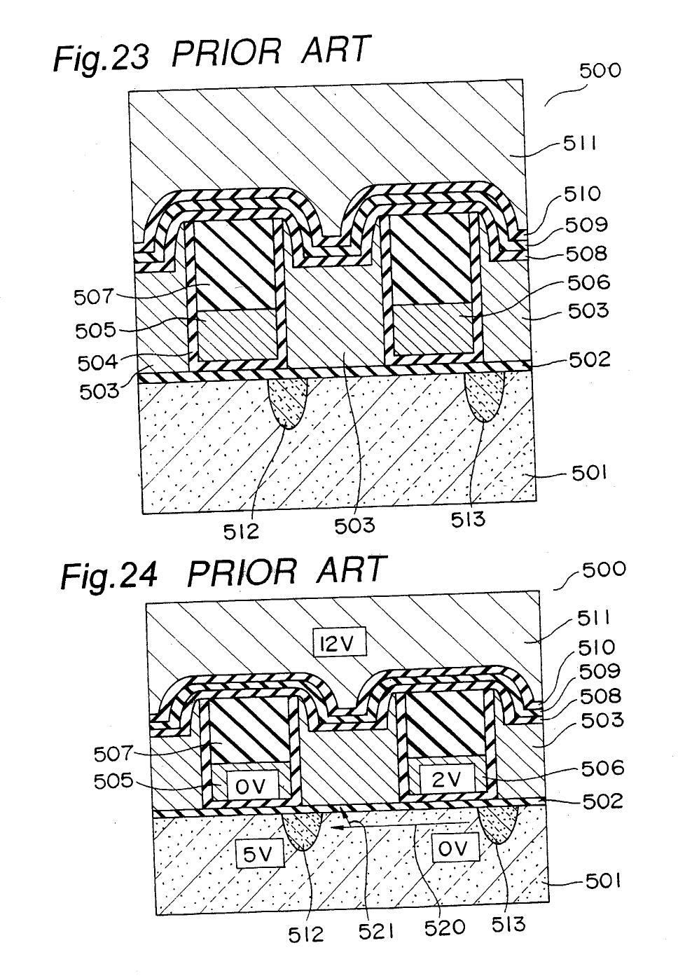

### DETAILED DESCRIPTION OF THE PREFERRED EMBODIMENTS

Preferred Embodiment 1

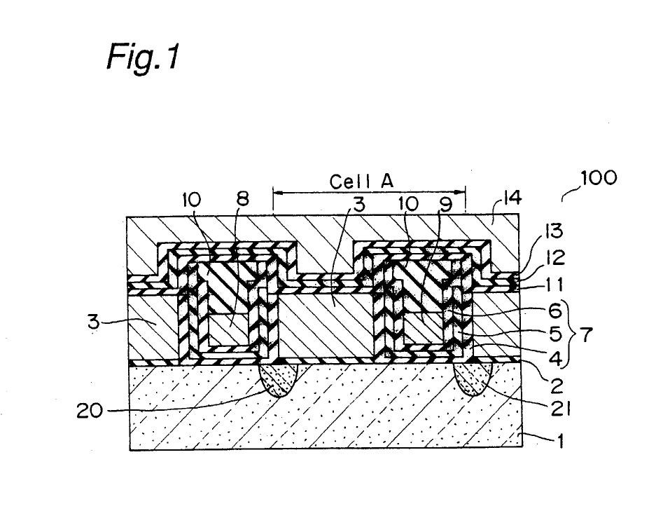

FIG. 1 is a sectional view of a nonvolatile semiconductor memory according to this preferred embodiment, indicated in its entirety as 100. The nonvolatile semiconductor memory 100 includes a silicon substrate 1. Provided on the silicon substrate 1 is a gate oxide film 2 made of silicon oxide. Deposited on the gate oxide film 2 is a polycrystalline silicon layer. Grooves are formed in the polycrystalline silicon layer. Only a portion of the polycrystalline silicon layer sandwiched between the grooves is left below a word line 14 after etching process, to form a floating gate (FG) 3, which is described later. The gate oxide film 2 on the bottom of the grooves is removed. An ONO film 7 made of a silicon oxide film 4, a silicon nitride film 5, and a silicon oxide film 6 is formed on the inner wall of each groove. Loaded into the grooves covered with the ONO film 7 are an embedded gates (third gates) 8 and 9, and silicon oxide film 10. Formed on floating gate 3 and a silicon oxide layer 10 as an insulating layer are a silicon oxide layer 11, a silicon nitride layer 12, and a silicon oxide layer 13 (ONO film). Formed thereon is a word line 14 made of polycrystalline silicon. In the silicon substrate 1, diffusion layers made of impurities are selectively formed to provide bit lines 20 and 21.

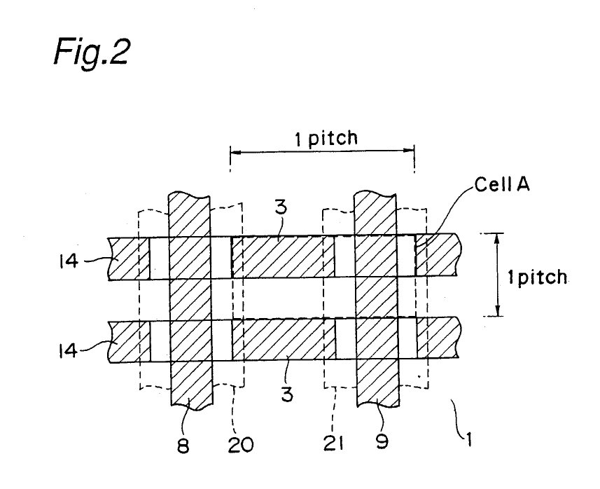

FIG. 2 is a schematic view illustrating the configuration of the floating gates 3, the embedded gates (third gates) 8 and 9, the word lines 14, and the bit lines 20 and 21 seen from the top face of the nonvolatile semiconductor memory 100 of FIG. 1.

The silicon substrate 1 includes the bit lines 20 and 21 disposed substantially in parallel with each other. Further, the embedded gates 8 and 9 are provided above the silicon substrate 1 so as to be substantially parallel to the bit lines 20 and 21, respectively. The word lines 14 are provided above the embedded gate 8 and 9 so as to be substantially orthogonal thereto.

The floating gates 3 are provided above the channel region sandwiched between the two bit lines 20 and 21 in the silicon substrate 1.

In FIG. 2, cell A, a unit of memory cell, is indicated

The nonvolatile semiconductor memory 100 includes a plurality of cells A. A cell A is the unit of memory cell. As shown in FIG. 1, each cell A includes a stacked gate type memory section for injecting hot electrons moving between the bit lines 20 and 21 into the floating gate 3 for storage, and a MONOS type memory section for injecting hot electrons into the ONO film 7 for storage (see U.S. Pat. No. 6,011,725, for example).

For such a nonvolatile semiconductor memory 100, the floating gate 3 in the stacked gate type memory section acts as an access gate for writing into the MONOS type memory section. The embedded gate 9 in the MONOS memory section acts as an access gate for writing into the stacked gate type memory section.

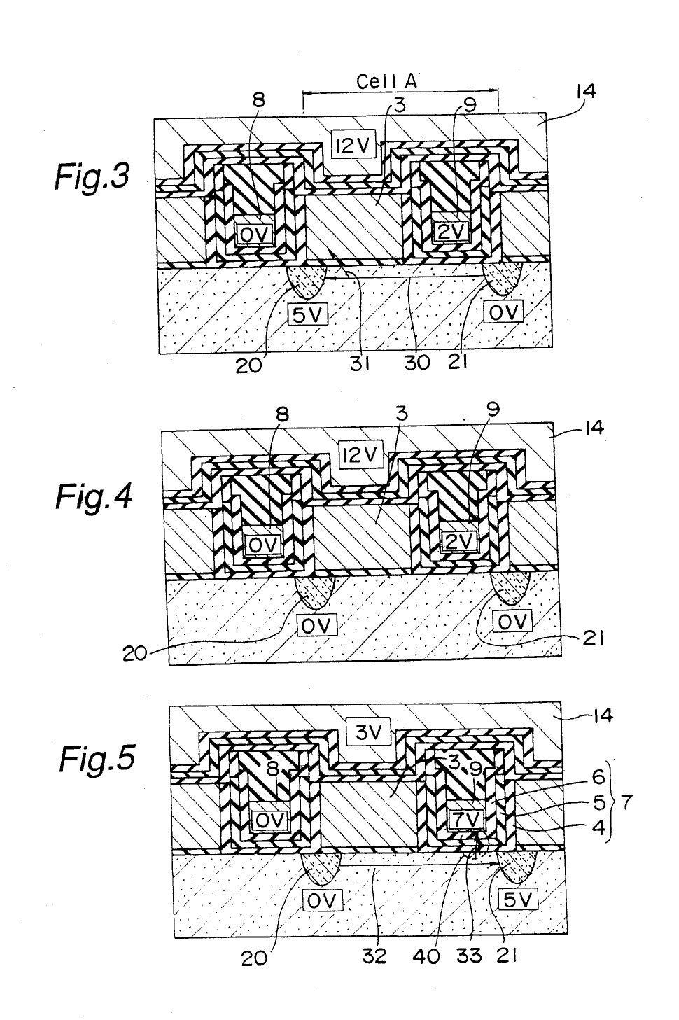

Next, referring to FIGS. 3 to 8, descriptions are provided of the operations of the nonvolatile semiconductor memory 100 in each of write (programming), read (reading), and erase (easing) processes. The nonvolatile semiconductor memory 100 is structured to have repetition of unit cells A (see FIG. 3). Therefore, after the description of the operations of a single unit cell A, the operations of the entire nonvolatile semiconductor memory 100 are described.

The process of programming the unit cell A includes the following three steps 1 through 3.

Step 1: In this step, writing into the stacked gate type memory section, i.e. writing into the floating gate (FG) 3 is performed. This step is substantially the same as the programming process of the nonvolatile semiconductor memory 500.

As shown in FIG. 3, the bit lines 20 and 21 are set to 5V and 0V, respectively. The word line 14 is set to 12V, and the embedded gate 9 is set to 2V. In this state, electrons move in the direction shown by arrow 30 to form hot electrons. These hot electrons are attracted by the voltage of the word line 14 (see arrow 31), and injected into the floating gate 3 for storage. Especially, setting the embedded gate 9 to a low voltage improves the efficiency of generation of hot electrons.

FIG. 4 shows an erase state before a process of writing into the floating gate 3 is performed. Both of the bit lines 20 and 21 are set to 0V. The electric potential of the bit line 20 can be any voltage equal or below 3V. The voltages of the embedded gates 8 and 9 and the word line 14 are the same as those of the programming process shown in FIG. 3.

Step 2: In this step, writing into a MONOS type memory section, i.e. writing into the region 40 of the silicon nitride film 5 in the ONO film 7 (hereinafter referred to as “MONOS region 40”), is performed. In Step 2, this programming operation is performed only for the cells in which writing into the floating gate 3 has not been performed in Step 1.

In this step, as shown FIG. 5, the bit lines 20 and 21 are set to 0V and 5V, respectively. A voltage of 3V is applied to the word line 14. This makes the floating gate 3 to a voltage of about 3V (the floating gate 3 having no electrical charge) and the channel below the floating gate 3 (threshold value: about 3V) is turned on. Further, the embedded gates 8 and 9 are set to 0V and 7V (about 7V to about 11V), respectively. In this state, electrons move in the direction shown by arrow 32 to form hot electrons. These hot electrons are attracted by the voltage of the word line 14 (see arrow 33), and injected into the MONOS region 40 for storage. Especially, setting the embedded gate 9 to a low voltage improves the efficiency of generation of hot electrons. In this manner, the floating gate 3 acts like the embedded gates 506 of the above nonvolatile semiconductor memory 500.

In contrast, as shown in FIG. 6, when electrons have been injected into the floating gate 3 in Step 1, setting the word line 14 to 3V will not turn on the channel below the floating gate 3 (threshold value: about 3V) and cause movement of electrons. Therefore, writing into the MONOS region 40 is not performed.

Of course, when writing into the MONOS region 40 is not performed, the bit line 21 can be set to 0V. On the other hand, even when a voltage of 5V is applied to the bit lines 21 in all the cells, writing into the MONOS region 40 is not performed for the cells of which the floating gates 3 store electrons therein.

In this programming step, instead of applying a voltage of 5V to the bit lines 21 in all the cells, only the bit lines 21 in the cells of which the floating gates 3 store no electron therein can selectively be set to 5V.

Step 3: In this Step 3, in the reverse of Step 2, selective programming is performed on the MONOS regions 40 in the cells of which the floating gates 3 have been programmed. As shown in FIG. 7, in this step, the bit lines 20 and 21 are set to 0V and 5V, respectively. The embedded gates 8 and 9 are set to 0V and 7V, respectively. A voltage of 5V is applied to the word line 14. In this case, it is necessary that the channel below the floating gate 3 should be turned on even when electrical charge is stored in the floating gate 3. For this reason, the threshold value (Vth) of the floating gate 3 is set to 5 V or lower, preferably to 3V.

In this process of writing into the MONOS region 40, application of a voltage to the floating gate 3 allows the floating gate 3 to act like the access gate 506 of the above nonvolatile semiconductor memory 500 and improves the efficiency of generation of hot electrons.

For the cells of which the floating gates 3 has not been programmed (written), or for the cells of which the floating gates 3 have been programmed but of which the MONOS regions 40 are not programmed, setting the voltage of the bit lines 21 to 0V, the same as that of the bit lines 20, as shown in FIG. 8, allows no information to be written into the MONOS regions 40.

As described above, for the nonvolatile semiconductor memory of a preferred embodiment 1, high-efficient writing into both the stacked gate type memory sections and the MONOS type memory sections can be performed with high efficiency of generation of hot electrons.

Additionally, because one cell can hold two-bit data, the cell area per one bit can be reduced, in comparison with that of a conventional nonvolatile semiconductor memory. While a conventional cell area is 4F², for example, that of the nonvolatile semiconductor memory of the present invention is about 2F², which is a half.

Further, setting the voltage of the embedded gates on both sides of a cell to be programmed to 0V can prevent unnecessary writing into the cell.

It is also possible to write into the MONOS type memory sections and then to the stacked gate type memory sections. However, because electrons stored in the MONOS regions 40 are unlikely to be repositioned, application of a voltage to the embedded gates 9 does not necessarily turn on all the channels below the embedded gates 9 uniformly. In contrast, when programming performed on the stacked gate type memory sections first, electrons are easily repositioned in the floating gates 3. Thus, the channels below the floating gates 3 are uniformly turned on.

For this reason, it is preferable to write into the stacked gate type memory sections and then into the MONOS type memory sections.

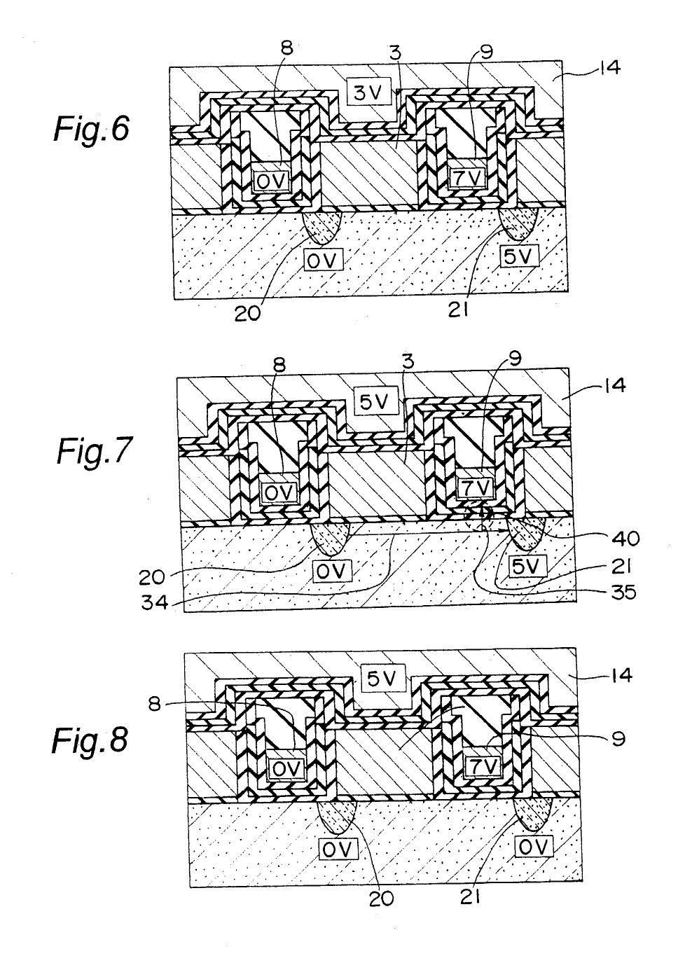

Next, a description is provided of a process of reading information from the nonvolatile semiconductor memory 100, referring to FIGS. 9 and 10. In the reading process, information is read from either of the stacked gate type memory section or the MONOS type memory section.

First, FIG. 9 shows a process of reading information from the stacked gate type memory section. In this process, the embedded gates 8 and 9 are set to 0V and 3V, respectively. This turns off the channel below the embedded gate 8 and turns on the channel below the embedded gate 9. A voltage of 3V is applied to the word line 14. When electrons exist in floating gate 3, the channel below floating gate 3 remains off. On the other hand, when electrons exist in the floating gate 3, the channel is turned on. Thus, setting the bit lines 20 and 21 to 0V and 2V, respectively, allows the state of the floating gate 3 to be read out.

Next, FIG. 10 shows a process of reading information from the MONOS type memory section. In this process, the embedded gates 8 and 9 are set to 0V and 3V, respectively. This turns off the channel below the embedded gate 8 and turns on the channel below the embedded gate 9. Setting the voltage of the word line 14 to 5V allows the channel below the floating gate 3 to be turned on, whether the floating gate 3 is charged or not. Setting the bit lines 20 and 21 to 2V and 0V, respectively, in this state allows the state of the MONOS 40 to be read out.

In these reading processes, when information in either of the stacked gate type memory or the MONOS type memory is read out, the operation of reading from one type of memory is not influenced by the state of the other type of memory. Therefore, excellent reading can be performed even when the cell area per bit is 2F², for example.

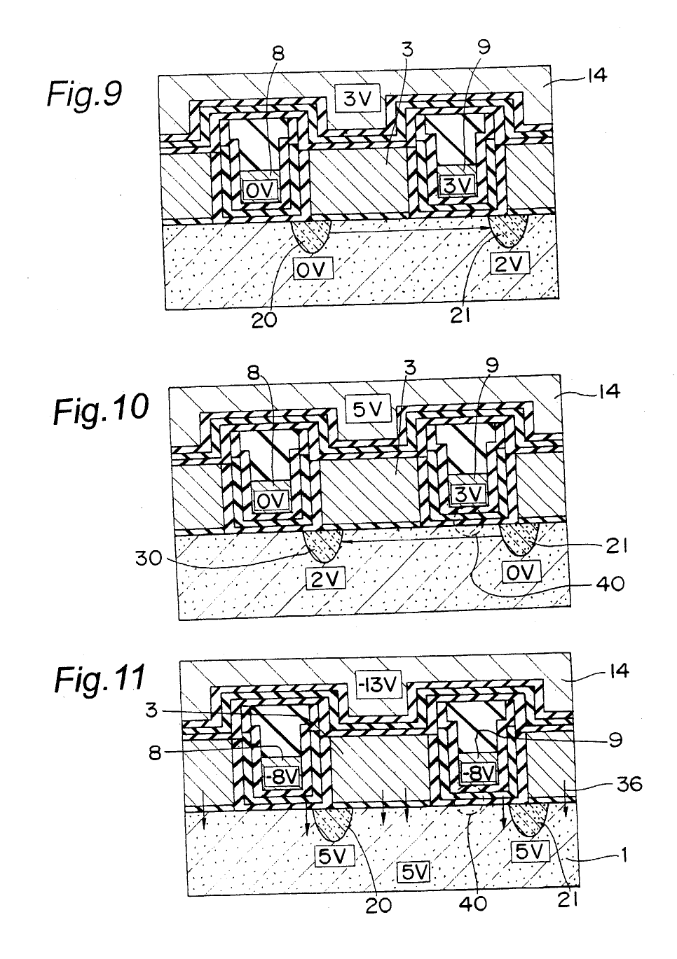

At last, FIG. 11 shows a process of erasing information both in the stacked gate memory section and in the MONOS type memory section. In this process, while the silicon substrate 1 including the bit lines 20 and 21 is set to 5V, both the embedded gates 8 and 9 are set to −8V and the word line is set to −13V. This allows electrons stored both in the floating gate 3 and in the MONOS region 40 to move toward the silicon substrate 1 for emission. Thus, information in both the stacked gate type memory section and the MONOS type memory section can be erased.

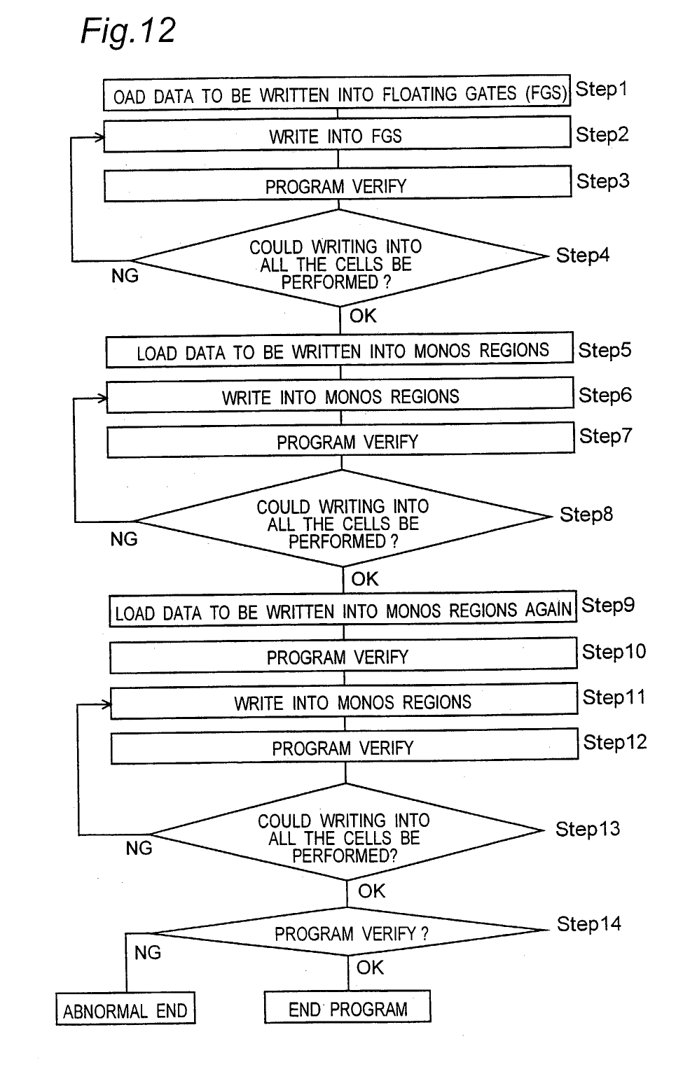

Next, a brief description is provided of the operations of the nonvolatile semiconductor memory 100 including a plurality of unit cells A. FIG. 12 is a flowchart showing a process of writing into the nonvolatile semiconductor memory 100. The flowchart includes Steps 1 through 14. Each step is described hereinafter.

Step 1: First, a step of writing information into the stacked gate type memory sections in a plurality of cells is performed. In this step, data to be written into the floating gates (FGs) of the stacked gate type memory sections is loaded into a buffer.

Step 2: The data is written into the stacked gate type memory sections in predetermined cells by applying pulse-like write enable signals (write pulses). The process of writing into each cell is as described above.

Step 3: The information that is stored in the buffer and to be written into the cells is compared with the information that has actually been written into the cells to check if the information has accurately been written (program verify).

Step 4: When it is verified in Step 3 that the information has accurately been written, the procedure goes to Step 5. On the other hand, the information has not accurately been written, the procedure returns to Step 2 and the information is written again.

Step 5: Data to be written into the MONOS regions in the MONOS type memory sections is loaded into the buffer. In this step, the information to be written into the MONOS type memory sections in all the cells is prepared, whether the information has been written into all the floating gates or not.

Step 6: The data is written into the MONOS type memory sections in predetermined cells by applying pulse-like write enable signals (write pulses). The process of writing into each cell is as described above.

However, as described above, the information is not written into the cells of which the floating gates store electrical charge, although the information is written into the cell of which the floating gates store no charge (see FIGS. 5 and 6).

Step 7: The information that is stored in the buffer and to be written into the cells is compared with the information that has actually been written into the cells to check if the information has accurately been written (program verify).

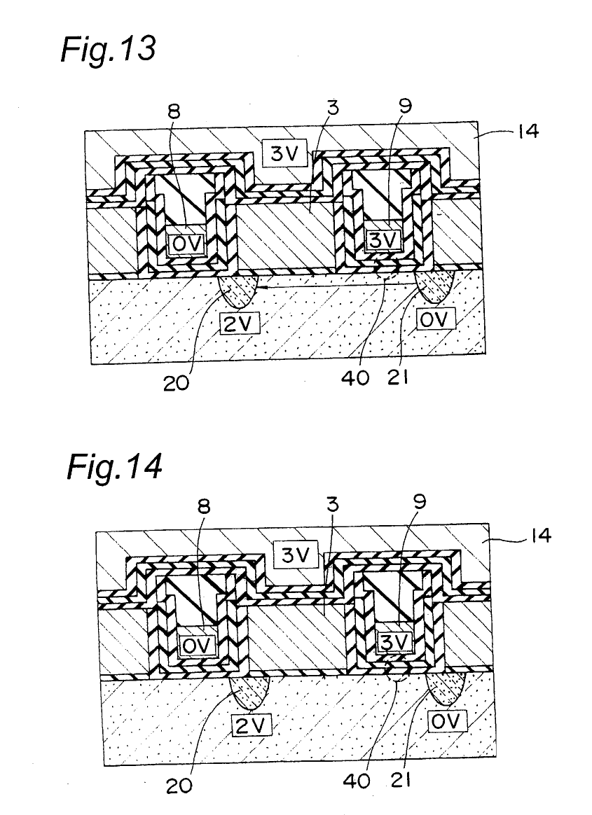

In this step, as shown in FIG. 13, a verify operation is performed while the bit lines 20 and 21 are set to 2V and 0V, respectively, the embedded gates 8 and 9 are set to 0V and 3V, respectively, and the word line 14 is set to 3V. When the floating gate 3 stores electrical charge, the channel below the floating gate 3 is turned off, as shown in FIG. 14. Thus, no current flows between the bit lines 20 and 21.

Step 8: When it is verified in Step 7 that the information has accurately been written, the procedure goes to Step 9. On the other hand, the information has not accurately been written, the procedure returns to Step 6 and the information is written again.

As for a cell of which the floating gate 3 stores no electrical charge (unprogrammed) and of which the MONOS region stores electrical charge (programmed), it is determined that a process of writing into the cell has been completed, like a cell of which the floating gate 3 stores electrical charge (programmed).

As for a cell of which the floating gate 3 stores electrical charge (programmed), it has already been determined that writing into the cell is completed.

Step 9: Like Step 5, data to be written into the MONOS regions in the MONOS type memory sections is loaded into the buffer again.

Step 10: Prior to writing into the MONOS regions in the MONOS type memory sections, a verify operation is performed while the bit lines 20 and 21 are set to 2V and 0V, respectively, the embedded gates 8 and 9 are set to 0V and 3V, respectively, and the word line 14 is set to 5V, as shown in FIG. 15. Then, cells of which the floating gates 3 store electrical charge and of which the MONOS regions store no electrical charge are extracted.

Step 11: Electrical charge is injected into the MONOS regions in the cells extracted in Step 10 for storage. The programming process is completed.

Step 12: The data written into the cells is verified.

Step 13: When it is verified in Step 12 that the information has accurately been written, all the programming process is completed. In this case, the procedure goes to Step 14. On the other hand, the information has not accurately been written, the procedure returns to Step 11 and the information is written again.

Step 14: The process of writing into the cells is completed in Step 13. However, it can also be verified that all the information has accurately been written into the cells in this Step 14. In Step 14, as shown in FIG. 16, the bit lines 20 and 21 are set to 0V and 2V, respectively, the embedded gates 8 and 9 are set to 0V and 3V, respectively, and the word line 14 is set to 5V. When all the cells have electrical continuity with these settings, it is determined that accurate programming is completed and the program ends. On the other hand, when some cells have no electrical continuity, the program ends showing abnormality.

Programming (writing information into) the nonvolatile semiconductor memory 100 having a plurality of cells according to these steps can reduce writing time, in comparison with the case where data to be supplied into the MONOS type memory sections is selected and written according to whether the stacked gate type memory sections have been programmed or not.

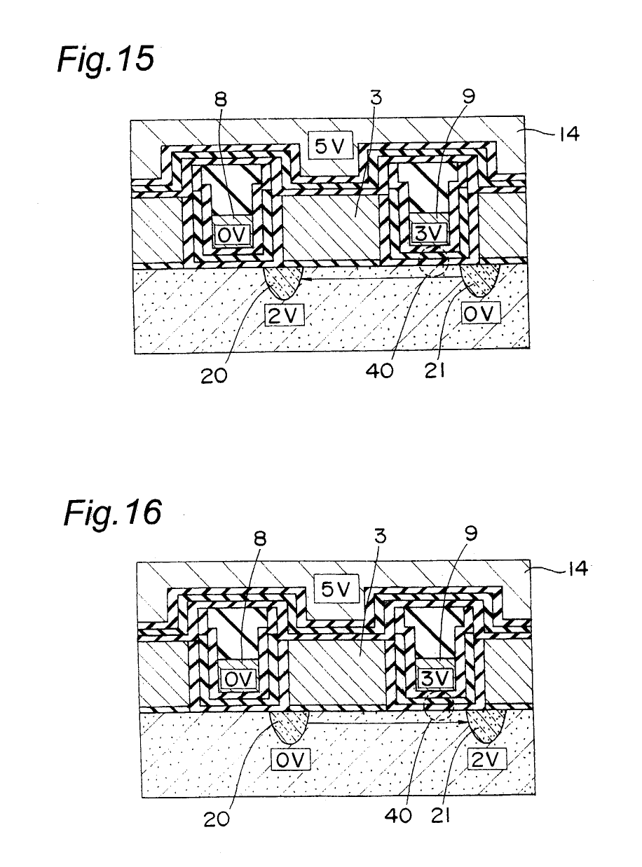

FIG. 17 shows another nonvolatile semiconductor memory according to the preferred embodiment 1, indicated its entirety as 101. In FIG. 17, same or corresponding elements used in FIG. 1 are denoted with the same reference numbers.

While a silicon oxide film 11 is formed by the CVD method in the above-mentioned nonvolatile semiconductor memory 100 (see Step 7), it is formed by a thermal oxidation method in the nonvolatile semiconductor memory 101. As a result, the silicon oxide layer 11 is formed only on the top face of the floating gate 3 made of polycrystalline silicon.

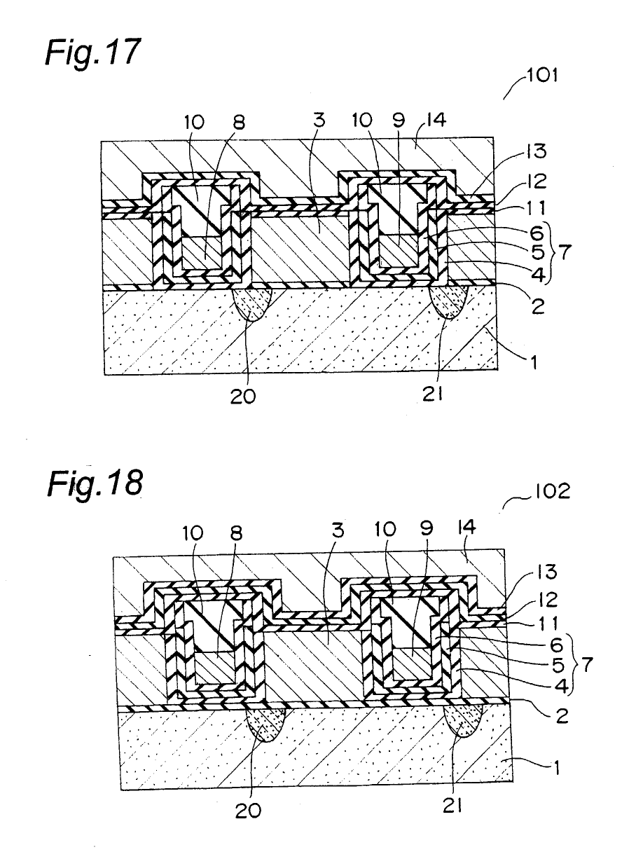

FIG. 18 shows still another nonvolatile semiconductor memory according to the preferred embodiment 1, indicated its entirety as 102. In FIG. 18, same or corresponding elements used in FIG. 1 are denoted with the same reference numbers.

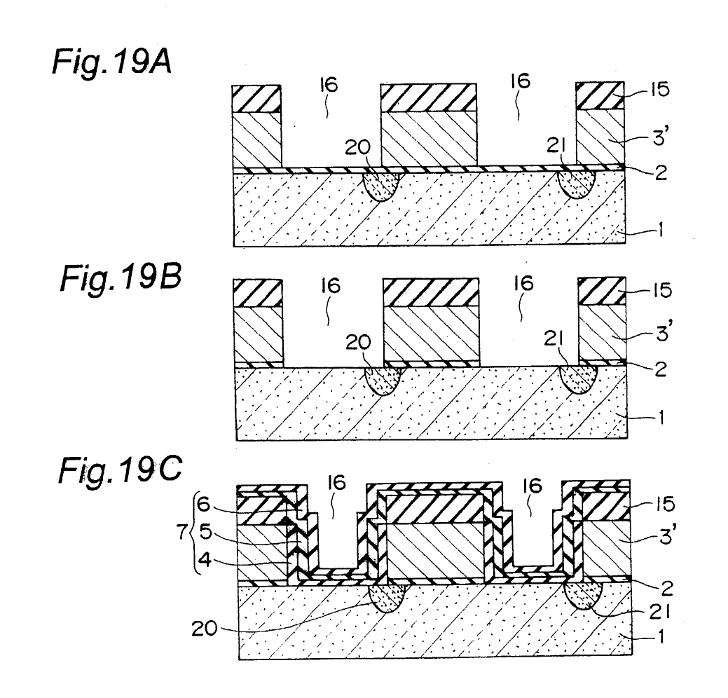

While gate oxide film 2 is completely removed from the bottom of grooves 16 in Step 2 (FIG. 19B) in the above-mentioned nonvolatile semiconductor memory 100, the gate oxide film 2 is left on the bottom of the grooves in the nonvolatile semiconductor memory 102 shown in FIG. 18. In this manner, the ONO films 7 can also be formed on the gate oxide layer 2. In this case, the total thickness of the gate oxide film 2 and the silicon oxide film 4 is controlled so as to be suitable for injection of electrons into the MONOS region for storage.

Preferred Embodiment 2

FIGS. 19A-19G show sectional views of the nonvolatile semiconductor memory 100 in each step of the producing method thereof. The producing method includes the following Steps 1 through 8.

Step 1: As shown in FIG. 19A, a gate oxide film 2 is formed on a p-type silicon substrate 1 by the thermal oxidation method, for example. Subsequently, a polycrystalline silicon layer doped with p-type impurities, and a silicon nitride film are deposited. Then, grooves 16 are formed using general photolithography and etching technologies. Thus, a polycrystalline silicon layer 3′ and a silicon nitride film 15 laminated thereon are formed. Further, using oblique ion implantation method, n-type impurity is selectively implanted into the silicon substrate 1 to form bit lines 20 and 21 (local bit line 20 and local source line 21, respectively). Alternatively, n-type bit lines 20 and 21 can be formed in a p-type well region formed in the silicon substrate.

Step 2: As shown in FIG. 19B, the gate oxide film 2 on the bottom of the grooves 16 is removed, using dilute hydrofluoric acid, for example.

Step 3: As shown in FIG. 19C, a silicon oxide film 4 is formed by the thermal oxidation method. Further, a silicon nitride film 5 and a silicon oxide film 6 are formed by the CVD method. The silicon oxide film 4 is formed on the surface of the silicon substrate 1 that is exposed on the bottom of each groove 16 and the sidewalls of the polycrystalline silicon layer 3′ that are not covered with a silicon nitride film 15. Because the concentration of the p-type impurity in the polycrystalline silicon layer 3′ is higher than that of the p-type impurity in silicon substrate 1, the silicon oxide film formed on the sidewalls of polycrystalline silicon layer 3′ is thicker than the silicon oxide film formed on the surface of the silicon substrate 1.

The silicon oxide film 4 on the surface of the silicon substrate 1 is about 3 nm in thickness. The thickness of the silicon nitride film 5 and the silicon oxide film 6 are about 6 nm and 5 nm, respectively.

Step 4: As shown in FIG. 19D, a conductive layer of polycrystalline silicon is formed over the entire surface by the CVD method and etched back to form embedded gates (third gates) 8 and 9 in grooves 16. Subsequently, a silicon oxide film 10 is deposited over the entire surface.

Step 5: As shown in FIG. 19E, the CMP process is performed using the silicon nitride film 15 as a stopper layer to leave the silicon oxide film 10 in grooves 16 only. The CMP process also removes the silicon nitride film 5, the silicon oxide film 6 on the silicon nitride film 15.

Step 6: As shown in FIG. 19F, the silicon nitride film 15 and part of the silicon nitride film 5 are removed using hot phosphoric acid, for example.

Step 7: As shown in FIG. 19G, a silicon oxide film 11, a silicon nitride film 12, and an silicon oxide film 13 are sequentially deposited by the CVD method.

Step 8: A polycrystalline silicon film is deposited on the entire surface. Then the polycrystalline silicon film is etched using a resist mask to form word lines 14 extending in the direction substantially orthogonal to embedded gates (third gates) 8 and 9. Subsequently, the polycrystalline silicon layer 3′ is etched using the same resist mask and left only below the word lines 14 to form a floating gates (FGs) 3. In this etching step, the embedded gates (third gates) 8 and 9 are protected by the upper silicon oxide layer 10.

At last, the resist layer is removed to complete the nonvolatile semiconductor memory 100 (see FIG. 1).

Preferred Embodiment 3

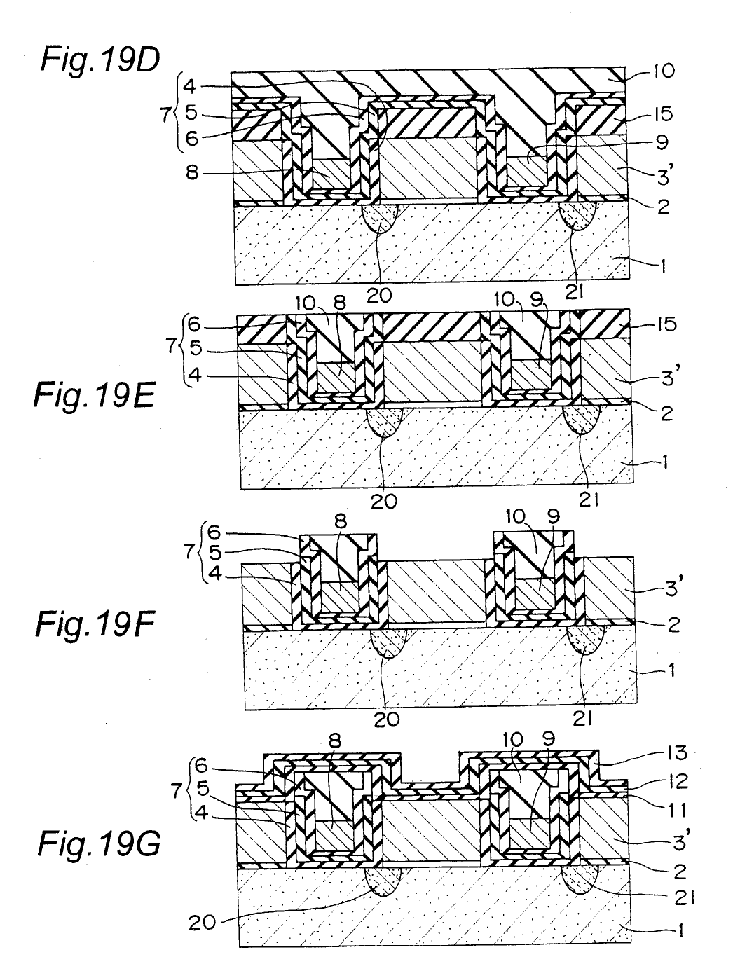

FIG. 20 shows a nonvolatile semiconductor memory according to a preferred embodiment 3, indicated its entirety as 200. In FIG. 20, same or corresponding elements used in FIG. 1 are denoted with the same reference numbers.

The nonvolatile semiconductor memory 200 is structured so that an ONO film 7 forms MONOS regions and also serves as an insulating layer between a floating gate 3 and a word line 14.

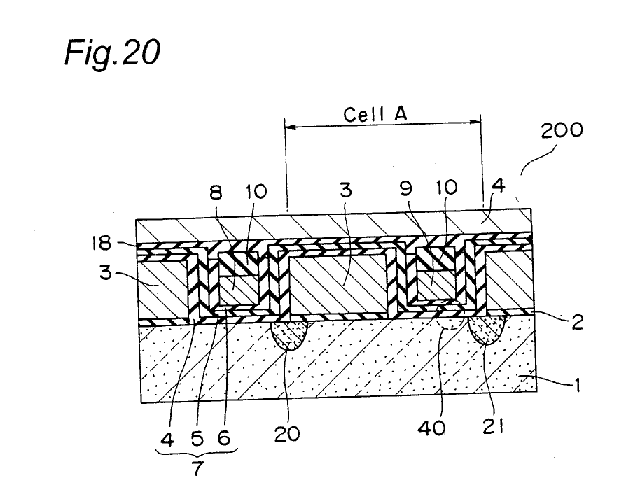

Next, a description is provided of a producing method of the nonvolatile semiconductor memory 200, referring to FIGS. 21A-21F. The producing method includes the following Steps 1 through 6.

Step 1: As shown in FIG. 21A, in a manner described in the preferred embodiment 1, a gate oxide film 2 and a polycrystalline silicon layer 3′ doped with a p-type impurity are formed on a p-type silicon substrate 1. An n-type impurity is injected into silicon substrate 1 to form bit lines (local bit line and local source line) 20 and 21, respectively.

Step 2: As shown in FIG. 21B, a silicon oxide film 4 is formed by the thermal oxidation method. The silicon oxide film 4 on the surface of the silicon substrate 1 is about 3 nm in thickness. In this step, the silicon oxide film 4 is also formed on the top face of the polycrystalline silicon layer 3′. Subsequently, a silicon nitride film 5 and a silicon oxide film 6 are sequentially formed by CVD method. The silicon oxide film 4, the silicon nitride film 5, and the silicon oxide film 6 form an OMO film 7.

Step 3: As shown in FIG. 21C, a conductive layer 17 made of polycrystalline silicon doped with an impurity, for example, is formed on the entire surface by CVD method.

Step 4: As shown in FIG. 21D, the conductive layer 17 is etched back to form embedded gates (third gates) 8 and 9. The top face of embedded gates 8 and 9 is made substantially as high as the top face of the polycrystalline silicon layer 3′.

Step 5: As shown in FIG. 21E, the top face of the silicon oxide film 6 is etched by dilute hydrofluoric acid or the like.

Step 6: As shown in FIG. 21F, the top face of the exposed embedded gates 8 and 9 is oxidized to form a silicon oxide film 22 about 50 nm in thickness. Further, a silicon oxide layer 18 is formed by CVD method.

Step 7: A polycrystalline silicon film is deposited on the entire surface. The polycrystalline silicon film is etched using a resist mask to form word lines 14 extending in the direction substantially orthogonal to the embedded gates (third gates) 8 and 9. Subsequently, the polycrystalline silicon layer 3′ is etched using the same resist mask and left only below the word lines 14 to form a floating gates (FGs) 3. In this etching step, the embedded gates (third gates) 8 and 9 are protected by the upper silicon oxide layer 10.

At last, the resist layer is removed to complete the nonvolatile semiconductor memory 200 shown in FIG. 20.

The configuration of the floating gates 3 or the like in the nonvolatile semiconductor memory 200 is the same as that of the nonvolatile semiconductor-memory 100 shown in FIG. 2.

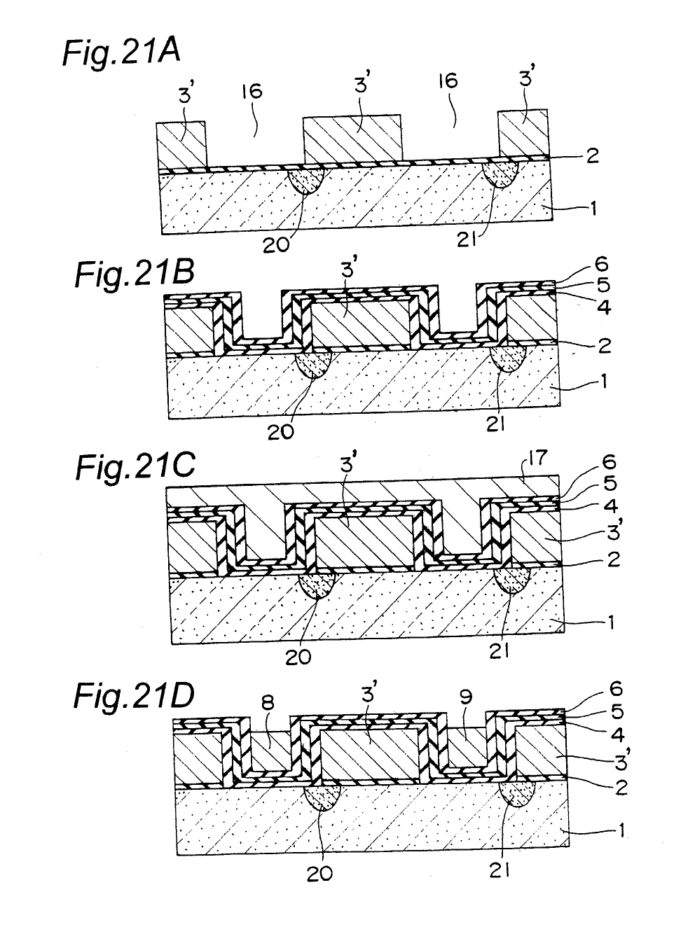

As shown in a nonvolatile semiconductor memory 201 of FIG. 22, all the insulating film on the floating gate 3 can be made of an ONO film that is the same as the ONO film 7 in the MONOS region.

Such a nonvolatile semiconductor memory 201 is made by forming a silicon oxide film 10 by the thermal oxidation method after the Step 4 (FIG. 21D) and forming word lines 14 on the oxide layer.

As described above, in the nonvolatile semiconductor memory, the ONO film 7 in the MONOS type memory section for storing electrons is also used as the insulating film between the floating gate 3 in the stacked gate type memory section and the word line 14. This simplifies the structure of the device. Especially, because the silicon oxide film 4 and the silicon nitride film 5 are formed in the same step, the producing process can also be simplified.

The operations of the nonvolatile semiconductor memories 200 and 201 are substantially the same as those of the above-mentioned nonvolatile semiconductor memory 100. In other words, for cell A shown in FIG. 20, electrons are stored in the floating gate 3 in the stacked gate type memory section and the MONOS region 40 in the MONOS type memory section.

The write, read, and erase processes are also the same as described above.

As can be seen from the above descriptions, the nonvolatile semiconductor memory of the present invention with the stacked gate type memory sections and the MONOS type memory sections has a cell area per bit smaller than that of a conventional nonvolatile semiconductor memory, thereby allowing higher integration of the memory.

The nonvolatile semiconductor memory of the present invention can reduce the amount of current required for writing and thus write time.

The method of producing the nonvolatile semiconductor memory of the present invention allows fabrication of a highly integrated nonvolatile semiconductor memory with a relatively simple process.

What is claimed is:

1. A nonvolatile semiconductor memory for storing electrical charge to store information, comprising:
a semiconductor substrate comprising a pair of bit lines disposed substantially in parallel with each other, and a channel region sandwiched between the bit lines;
an embedded gate extending above the channel region substantially in parallel with the bit lines, the embedded gate made of a conductive layer being provided via ONO film made of a nitride film sandwiched by oxide films;
a floating gate made of a conductive layer provided above the channel region via gate oxide film, along the embedded gate;
an insulating layer covering the floating gate and the embedded gate; and
a word line provided on the insulating layer on the floating gate, substantially orthogonal to the bit lines;
wherein electrical charge is stored into the floating gate and/or the nitride film included in the ONO film.

2. A nonvolatile semiconductor memory according to claim 1, wherein two layers of the oxide film and the nitride film in the ONO film are also formed on the floating gate to constitute the insulating layer.

3. A nonvolatile semiconductor memory according to claim 1, wherein three layers of the oxide film, the nitride film, and the oxide film constituting the ONO film are also formed on the floating gate to constitute the insulating layer.

4. A nonvolatile semiconductor memory according to claim 1, wherein the insulating layer comprises an oxide film made of the thermally oxidized top face of the floating gate.

5. A nonvolatile semiconductor memory according to claim 1, wherein the embedded gate is further provided via gate oxide film formed on the surface of the channel region.

6. A method of programming a nonvolatile semiconductor memory, the nonvolatile semiconductor memory comprising:
a semiconductor substrate comprising a channel region for allowing movement of electrical charge therein, and first and second bit lines disposed substantially in parallel with each other so as to sandwich the channel region;
a floating gate provided above the semiconductor substrate along the first bit line;
an embedded gate extending along the second bit line, via ONO film; and
a word line provided above the floating gate and the embedded gate, substantially orthogonal to the bit lines; the method comprising the steps of:
a) storing electrical charge moving from the second bit line to the first bit line into the floating gate and/or
b) storing electrical charge moving from the first bit line to the second bit line into the ONO film.

7. A method of programming a nonvolatile semiconductor memory according to claim 6, wherein, in the step a), the electrical charge is stored with the embedded gate set to a predetermined electric potential.

8. A method of programming a nonvolatile semiconductor memory according to claim 6, wherein the step b) comprising the steps of:
setting the word line to a first electric potential, closing the channel below the floating gate when electrical charge is stored in the floating gate, and opening the channel below the floating gate to store electrical charge into the ONO film when electrical charge is not stored in the floating gate.

9. A method of programming a nonvolatile semiconductor memory according to claim 8, wherein the step b) further comprising the steps of:
setting the word line to a second electric potential higher than the first electric potential, and opening the channel below the floating gate to store electrical charge into the ONO film when electrical charge is stored in the floating gate.

10. A method of programming a nonvolatile semiconductor memory according to claim 6,
wherein, in the step a), the embedded gate acts as an access gate to inject the electrical charge into the floating gate as a hot electron; and
wherein, in the step b), the floating gate acts as an access gate to inject the electrical charge into the ONO film as a hot electron.
